(19) United States
(12) Patent Application Publication
(10) Pub. No.: US 2025/0155494 A1
(43) Pub. Date: May 15, 2025

(54) AGING PROFILE COMPONENTS

(71) Applicant: Micron Technology, Inc., Boise, ID (US)

(72) Inventors: Leon Zlotnik, Camino, CA (US); Evgeni Bassin, Pleasanton, CA (US)

(21) Appl. No.: 18/918,976

(22) Filed: Oct. 17, 2024

Related U.S. Application Data
(60) Provisional application No. 63/599,275, filed on Nov. 15, 2023.

(51) Int. Cl. G01R 31/28

(52) U.S. Cl. CPC G01R 31/2874

(57) ABSTRACT

A method includes monitoring, by a temperature sensor, a temperature of a system on chip (SoC), determining temperature data of the SoC that includes an amount of time the SoC is operating at a plurality of different temperatures, normalizing the temperature data to a designated operating temperature, calculating an electromigration aging profile for the SoC based on the normalized temperature data, and determining a time-to-failure for the SoC based on the electromigration aging profile.

### PRIORITY INFORMATION

This application claims the benefit of U.S. Provisional Application No. 63/599,275, filed on Nov. 15, 2023, the contents of which are incorporated herein by reference.

### TECHNICAL FIELD

Embodiments of the disclosure relate generally to electronic systems, and more particularly to aging profile components.

### BACKGROUND

Various types of electronic devices such as logic circuits may store and process data. A logic circuit is an electronic circuit that processes digital signals or binary information, which can take on two possible values (usually represented as 0 and 1). The logic circuit can use logic gates to manipulate and transform the signals or binary information. Digital logic circuits can be used in a wide range of electronic devices including, for example, computers, calculators, digital clocks, and many other electronic devices that employ digital processing. Digital logic circuits can be designed to perform specific logical operations on digital inputs to generate digital outputs, and, in some instances, can be combined to form more complex circuits to perform more complex operations.

### BRIEF DESCRIPTION OF THE DRAWINGS

The present disclosure will be understood more fully from the detailed description given below and from the accompanying drawings of various embodiments of the disclosure.

FIG. 1 illustrates an example electronic system that includes a host, a controller, and a device in accordance with various embodiments of the present disclosure.

FIG. 2 illustrates a system for aging profile components in accordance with some embodiments of the disclosure.

FIG. 3 illustrates a method for determining an aging profile in accordance with some embodiments of the disclosure.

FIG. 4 is a block diagram of an example computer system in which embodiments of the disclosure may operate.

### DETAILED DESCRIPTION

Aspects of the present disclosure are directed to generating an aging profile, in particular to electronic systems that include an aging profile component. Devices that utilize electrical components such as a metal-oxide-semiconductor field-effect transistor (MOSFET) (e.g., P-type Metal-Oxide-Semiconductor (PMOS), N-type Metal-Oxide-Semiconductor (NMOS), etc.) and/or other logic circuits can deteriorate or age (e.g., decrease in performance, etc.) over a lifespan of the device. For example, logical circuits and/or wiring of a system-on-chip (SoC) can deteriorate over the lifespan of utilizing the device. In some examples, the aging mechanisms of the devices can include, but are not limited to: electromigration (E M), bias temperature instability (BTI), and/or hot carrier injection (HCl).

As used herein, the electromigration aging mechanism can refer to a physical phenomenon that occurs in electronic devices, particularly in metallic conductors, when the movement of atoms or ions within the conductor is influenced by the flow of electric current over time. The movement of atomic species can lead to a gradual degradation and/or failure of the conductor over time. For example, the movement of atomic species can result in an accumulation of metal ions that can lead to a formation of localized areas with a relatively higher ion density and stress.

As used herein, the bias temperature instability aging mechanism can refer to a degradation of transistor performance over time when subjected to a combination of electrical bias and/or elevated temperatures. In addition, as used herein, the hot carrier injection aging mechanism refers to high-energy electrons or holes that gain sufficient energy to overcome the energy barriers within the semiconductor material and are injected into the gate oxide or insulating layer. Although there are a plurality of aging mechanisms that can result in a degradation and/or failure of an electrical device (e.g., SoC, etc.), the electromigration aging mechanism can be a more limiting factor to device durability than the bias temperature instability or hot carrier injection. For example, the electromigration aging mechanism can have a greater effect on the overall device degradation at higher temperatures compared to the bias temperature instability and/or hot carrier injection aging mechanisms.

In some previous approaches, design alterations of the electrical device during a design cycle can be utilized to address the aging mechanisms. In some embodiments, the alterations during the design cycle include applying additional margins and/or derating factors during physical design. In addition, the alterations of the electrical device can include reducing voltage, working frequency, and/or working temperature. Furthermore, the alterations of the electrical device can include implementing wider or thicker wires among other design changes to alleviate the aging mechanisms associated with the electrical device.

These previous approaches can utilize the aging mechanisms to determine a time-to-failure (TTF) of the electrical device. In some embodiments, these previous approaches can utilize an accelerated aging (e.g., High-Temperature Operating Life (HTOL), etc.) to estimate the time-to-failure for the electrical device. However, the previous approaches that utilize accelerated aging are not able to adequately accelerate each of the plurality of aging mechanisms to match real world operating conditions. For example, the accelerated aging may not adequately account for how different voltages and/or different temperatures have different effects on each of the plurality of aging mechanisms. For example, relatively high voltages and/or relatively higher temperatures can affect the aging mechanisms differently compared to relatively lower voltages and/or relatively lower temperatures. Furthermore, profiles that resemble real world use case scenarios can be difficult since electrical devices such as an SoC can be utilized in a plurality of different devices that have very different operating conditions.

Aspects of the present disclosure address the above and other deficiencies by employing aging profile components to generate aging profiles. The aging profile components described herein can include aging statistics systems to collect real-time temperature data, voltage data, clocking data, among other data during operation of the electrical device. In these embodiments, the aging profile components can correlate the collected data and normalize the correlated temperature data to a particular aging mechanism temperature (e.g., designated operating temperature, designated temperature for statistical modeling, etc.). In some embodiments, the aging profile components can focus on the electromigration aging mechanism when it is determined that the electromigration aging mechanism is more limiting for a time-to-failure of the electrical device compared to other aging mechanisms. In a specific embodiment, an electromigration aging mechanism factor per temperature statistical model can be utilized to normalize the collected data to generate real-time aging profiles for a SoC utilizing data collected during operation of the SoC. In this way, the aging profiles of the SoC can be representative of real world conditions for a particular device under specific conditions. In some embodiments, settings of the particular device can be altered to adjust operating conditions based on the updated real-time aging profile.

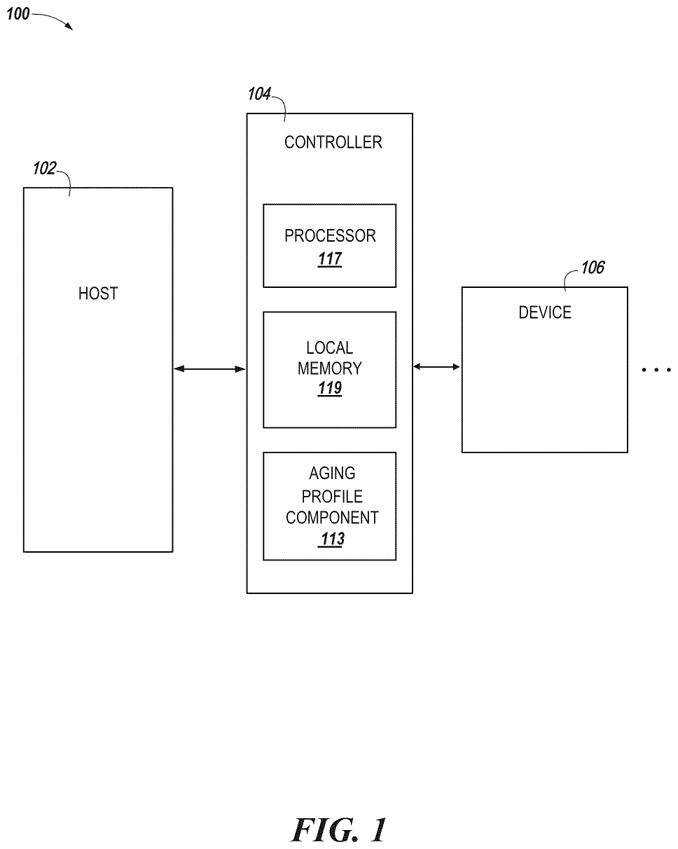

FIG. 1 illustrates an example electronic system 100 that includes a host 102, a controller 104, and a device 106 in accordance with various embodiments of the present disclosure.

The electronic system 100 can be, or can be part of, for example, a desktop computer, laptop computer, televisions, home theater system, gaming console, digital camera, network router and/or switch, printer, scanner, medical device, GPS navigation device, home device (e.g., thermostat, doorbell camera, security camera, smart lock, etc.), wearable device, industrial control system (e.g., automated industrial and/or control device) mobile computing device, a vehicle (e.g., airplane, drone, train, automobile, or other conveyance), Internet of Things (IoT) enabled device, embedded computer (e.g., one included in a vehicle, industrial equipment, or a networked commercial device), system-on-chip (SoC), chipset (e.g., a collection of integrated circuits), tile, Field-Programmable Gate Array (FPGA) structure (e.g., segmented FPGA structure), or other such device.

The electronic system 100 can be, or can include, a computing fabric. As used herein, the term “computing fabric” generally refers to a conveying, multiplexing, network, computing, or communication topology in which components pass data to each other through interconnecting switches, hubs, routers, multiplexers, buses, transmission lines and rings, cables, optical couplers and fibers, electromagnetic devices, or various other means. For example, a “computing fabric” can include various components (e.g., interconnects, crossbars, networks on chip, token rings, etc.) within a computing, memory, data storage and/or processing, network and/or telecommunication, artificial intelligence, control and/or telemetry, digital entertainment and/or other system, that facilitates in-chip and/or inter-chip communication.

The electronic system 100 includes a host 102. The host 102 can include a processor chipset and a software stack executed by the processor chipset. For example, the host 102 can be, or can include, a central processing unit (CPU) or a CPU complex that can be configured to execute an operating system.

The host 102 can be coupled to the controller 104 via a physical and/or logical host interface that operates based on various communication protocols and to provide control, address, data, and other signals to the controller 104 (e.g., to further cause the controller 104 to control the device 106). Examples of the interface between the host 102 and the controller 104 can include, but not limited to, a bus interface (e.g., a serial advanced technology attachment (SATA) interface, a Serial Attached SCSI (SAS) interface, a Serial Attached SCSI (SAS) interface, a Small Computer System Interface (SCSI), a peripheral component interconnect express (PCIe) interface, ISA, etc.), a memory interface (e.g., a double data rate (DDR) interface, a dual in-line memory module (DIMM) interface, an Open NAND Flash Interface (ONFI) interface, an NVM Express (NVMe) interface), a Fibre Channel, an UART interface, an I2C interface, a Serial Peripheral Interface (SPI), an Universal Serial Bus (USB) interface, an ethernet interface, a general-purpose input/output (GIPO) interface, a custom interface, etc.

The controller 104 is communicatively coupled to one or more electronic devices 106 such that signaling can be exchanged therebetween. Non-limiting examples of the devices 106 can include microcontrollers, microprocessors, digital logic circuits, analog circuits, light emitting diodes (LEDs), displays, sensors, motors, actuators, audio amplifiers, radio frequency (RF) circuits, test and measurement instruments (e.g., oscilloscopes, multimeters, etc.), automotive electronics, medical devices, telecommunication equipment, memory devices (e.g., volatile and/or non-volatile memory devices), graphics processing units, processors/co-processors, logic blocks, intellectual property (IP) cores, etc. As used herein, a “core” or “IP core” generally refers to one or more blocks of data and/or logic that form constituent components of an application-specific integrated circuit or field-programmable gate array. The circuit portion areas can be designed, built, and/or otherwise configured to perform specific tasks and/or functions within the systems described herein.

As shown in FIG. 1, the controller 104 can include a processing device (e.g., processor 117) that can execute instructions stored in a local memory 119 to perform various operations described herein. The controller 104 can include various special purpose circuitry in the form of an ASIC, FPGA, state machine, and/or other logic circuitry that can perform operations described herein. As an example, the controller 104 can be a memory controller.

In various embodiments, one or more constituent components (e.g., host 102, controller 104, device 106, etc.) of system 100 can be part of a SoC. In one example, a device 106 itself can correspond to an SoC, while the host 102 and the controller 104 are considered “external” to the SoC. In another example, the host 102 or the controller 104, or both, can be considered as a part of an SoC along with the device 106 being internal or external to the SoC.

As shown in FIG. 1, the controller 104 can include an aging profile component 113. The aging profile component 113 can be resident on the controller 104. As used herein, the term “resident on” refers to something that is physically located on a particular component. For example, the aging profile component 113 being “resident on” the controller 104, for example, refers to a condition in which the hardware circuitry that comprises the aging profile component 113 is physically located on the controller 104. The term “resident on” may be used interchangeably with other terms such as “deployed on” or “located on,” herein. In some embodiments, the aging profile component 113 is part of the host 102, an application, or an operating system. Although not shown in FIG. 1 so as to not obfuscate the drawings, the aging profile component 113 can include various circuitry to facilitate aspects of the disclosure described herein. For example, the aging profile component 113 can include various circuitry to facilitate generating an aging profile for an SoC.

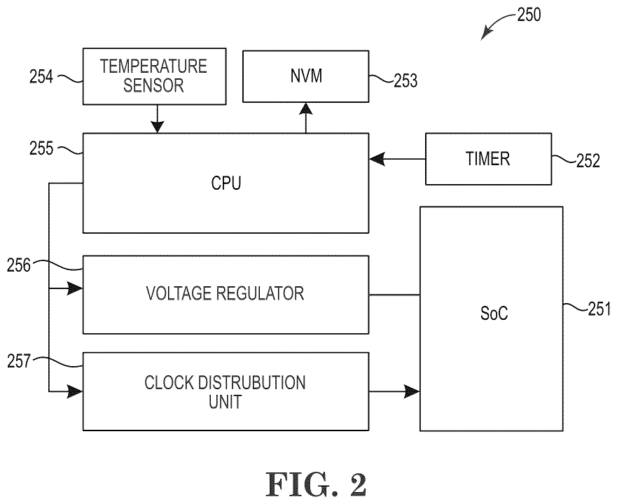

FIG. 2 illustrates a system 250 for aging profile components in accordance with some embodiments of the disclosure. The system 250 can include a system on chip 251 (SoC). The SoC 251 can be an integrated electronic circuit that combines multiple hardware components and/or functions of a computer system onto a semiconductor chip or die. In some embodiments, the components of the system 250 can be resident on the SoC 251 and/or remote from the SoC 251. For example, in some embodiments, one or more of the central processing unit 255 (CPU), voltage regulator 256, clock distribution unit 257, timer 252, non-volatile memory 253 (NVM), and/or temperature sensor 254 can be remote and/or resident on the SoC 251.

In some embodiments, the system 250 can include a temperature sensor 254 to monitor a temperature of the system 250 and/or the SoC 251 during operation of the SoC 251. In some embodiments, the temperature sensor 254 can include a plurality of temperature sensors. In some embodiments, the plurality of temperature sensors can be utilized to monitor a temperature of various locations of the system 250 and/or various locations of the SoC 251. In some embodiments, the system 250 can include a timer 252 to determine a time associated with the determined temperature from the temperature sensor 254. In this way, the CPU 255 can receive the temperature values from the temperature sensor 254 and corresponding time data from the timer 252 to determine an amount of time the system 250 or SoC 251 is operating at a particular temperature.

In some embodiments, the system 250 can include a voltage regulator 256. As used herein, a voltage regulator 256 can be a device that can maintain a relatively stable and consistent output voltage to the SoC 251. In some embodiments, the voltage regulator 256 can be a device or system of devices that can manipulate or alter an output voltage. For example, the voltage regulator 256 can include one or more of: a power supply, one or more converters, one or more inverters, one or more generators, among other electrical components that can alter a voltage or current. In another example, the voltage regulator 256 can include batteries or solar elements with a switch that connects different battery elements to manipulate the voltage.

In some embodiments, the voltage regulator 256 can include a voltage sensor and/or current sensor to monitor the output voltage and/or output current of the voltage regulator 256. In this way, the voltage sensor and/or current sensor can monitor the voltage and/or current provided to the SoC 251. As described herein, the detected voltage and/or detected current from the voltage regulator 256 can be correlated with an indicated time from the timer 252. In this way, the CPU 255 can receive the detected voltage and/or detected current values from the voltage regulator 256 and corresponding time data from the timer 252 to determine an amount of time the system 250 or the SoC 251 is operating at a particular voltage and/or at a particular current.

In some embodiments, the system 250 includes a clock distribution unit 257 that can generate clocking signals that are utilized by the SoC 251. In some embodiments, the clock distribution unit 257 can include hardware circuitry configured to generate periodically oscillating signals (e.g., square waves) that are applied to components of the system 250. In some embodiments, the clock distribution unit 257 can include monitoring circuitry to monitor the clocking signals and/or clocking frequency provided to the SoC 251. In these embodiments, the CPU 255 can receive the detected clocking signals and/or detected frequency of the clocking signals from the clock distribution unit 257 and corresponding time data from the timer 252 to determine an amount of time the system 250 or SoC 251 is operating at a particular clocking signal frequency.

As described further herein, the temperature data from the temperature sensor 254, voltage data from the voltage regulator 256, current data from the voltage regulator 256, and/or clocking data from the clock distribution unit 257 can be correlated with the timer data from the timer 252 and stored at the NVM 253 to be analyzed. In some embodiments, the system 250 can store the data to the NVM 253 periodically or at set operations. For example, the system 250 can store the data to the NVM 253 during a start up operation and/or store the data to the NVM 253 during a shut down operation.

In some embodiments, the CPU 255 can be configured to perform particular functions of an aging profile component 113 as described in reference to FIG. 1. For example, the CPU 255 can be configured to monitor temperature data of the system on chip (SoC) 251 received by the temperature sensor 254. In some embodiments, the CPU 255 can receive temperature data measured by a temperature sensor 254 associated with the SoC 251. As described further herein, the temperature sensor 254 can include a sensor element that can detect a temperature of the SoC 251 or components of the SoC 251. For example, the temperature sensor 254 can include one or more of thermocouples, resistive temperature detectors (RTDs), thermistors, or integrated circuit (IC) temperature sensors. In this way, the temperature sensor 254 can measure real-time temperature values of the SoC 251 during operation of the SoC 251.

The CPU 255 can be configured to monitor voltage data provided to the SoC 251 by the voltage regulator 256. In some embodiments, the SoC 251 can include a voltage regulator 256 to provide a voltage and/or current to components of the SoC 251. Voltage and/or current fluctuations can occur during operation of the SoC 251. A voltage monitor associated with the voltage regulator 256 and/or the SoC 251 can be utilized to monitor real-time voltage and/or current that is applied to the SoC 251 by the voltage regulator 256.

In other embodiments, the CPU 255 can be executed to monitor temperature data of the SoC 251 received by the temperature sensor 254 with corresponding time data received by the timer 252. As described herein, the CPU 255 can receive temperature data from a temperature sensor 254 and time data from a timer 252 such that the temperature data can be monitored with the corresponding time data. In this way, the CPU 255 can determine an amount of time the SoC 251 is operating at a plurality of different temperatures. In some embodiments, the CPU 255 can store the temperature data and corresponding time data in the NVM 253.

In some embodiments, the CPU 255 can be executed to monitor voltage data provided to the SoC 251 by the voltage regulator 256 with corresponding time data received by the timer 252. As described herein, the voltage data can be collected or monitored from a voltage regulator 256. The voltage data can include voltage values and/or current values that are provided to the SoC 251 by the voltage regulator 256. In some embodiments, the voltage data can be correlated with the corresponding voltage data such that the CPU 255 can determine an amount of time the SoC 251 is utilizing a particular voltage and/or current during operation.

The CPU 255 can be configured to correlate the temperature data and the voltage data with time data. Correlating the temperature data and the voltage data with time data can include storing the temperature data and the voltage data with a corresponding timestamp such that the time of measuring the temperature data and the voltage data can be identified. In this way, an amount of time the SoC 251 is operating at a particular temperature can be determined and an amount of time the SoC 251 is operating at a particular voltage and/or current can be determined. In some embodiments, the correlated temperature data and/or the correlated voltage data can be stored by a memory resource (e.g., NVM 253, etc.) associated with the SoC 251. For example, the correlated temperature data and/or the correlated voltage data can be stored during a shutdown operation and/or during a startup operation of the SoC 251.

In other embodiments, the timer 252 can be a counter (e.g., accumulator, etc.) that can be utilized to determine an amount of time or a quantity of time that the system 250 and/or SoC 251 are operating at a particular temperature identified by the temperature sensor 254, at a particular voltage identified by a voltage sensor, at a particular current identified by a current sensor, and/or at a particular frequency (e.g., clocking frequency) identified by a frequency sensor. In this way, the timer 252 can determine a first amount of time the temperature sensor 254 is at a first temperature and a second amount of time the temperature sensor 254 is at a second temperature. In a similar way, the timer 252 can determine a quantity of time the system 250 is operating at a plurality of different voltages, a plurality of different currents, and/or a plurality of different frequencies in a similar way.

In other embodiments, the CPU 255 can be executed to correlate the temperature data and the voltage data with corresponding time data received by the timer 252. In some embodiments, the CPU 255 can correlate the temperature data with the voltage data to determine an amount of time that the SoC 251 is operating at a particular temperature and corresponding voltage, current, and/or frequency. In this way, the CPU 255 can determine an amount of time the SoC 251 is operating at each of a plurality of temperatures, corresponding voltages, currents, and/or frequencies. For example, the CPU 255 can determine an amount of time the SoC 251 is operating at a temperature of 125° C., a voltage of 0.8 volts (V), a current of 250 milliamps (mA) and/or at a particular frequency. In this example, the CPU 255 can utilize the amount of time with the particular conditions to determine an aging profile with a corresponding time-to-failure analysis for an SoC 251 that is operating under the particular conditions for the determined amount of time.

The CPU 255 can be configured to normalize the temperature data to a designated operating temperature of the SoC 251. As used herein, a designated operating temperature of the SoC 251 can be a designated temperature for calculating a time-to-failure for a particular aging mechanism utilizing a statistical model for the particular aging mechanism. In some embodiments, statistical electromigration response per temperature data for the SoC 251 can be utilized to determine aging of the SoC 251 at the designated temperature. For example, the designated operating temperature can be a normalized electromigration factor per temperature value determined from a statistical model. In this example, the temperature value can be 125 degrees Celsius (° C.) and a time-to-failure can be approximately three years. In this example, the temperature data received from a temperature sensor can be normalized to 125 degrees and the time-to-failure can be normalized for the time period of operation. For example, one hour at 110° C. can be normalized to 0.30 hours at 125° C. In this way, the time-to-failure of the aging profile for the SoC 251 can be updated based on real-time operation of the SoC 251.

In other embodiments, the CPU 255 can be executed to normalize the temperature data to a designated operating temperature of the SoC 251. As described herein, the CPU 255 can utilize a statistical model of electromigration aging mechanisms or statistical models of other types of aging mechanisms to determine the aging profile and/or time-to-failure for the SoC 251. The statistical model of the aging mechanism can utilize a designated operating temperature. Since the SoC 251 operates a plurality of different temperatures during real world operation, the CPU 255 can normalize the temperature data to the designated operating temperature of the statistical model to determine the time-to-failure for the SoC 251.

For example, the designated operating temperature for the statistical model can be 125° C. with a time to failure of three years for a particular SoC 251. That is, the SoC 251 would statistically fail after three years of operation at a temperature of 125° C. In this example, the CPU 255 can convert an operating temperature of 110° C. for an amount of time of 1 hour to an operating temperature of 125° C. for 0.30 hours to calculate the time-to-failure. In this example, the time-to-failure for the SoC 251 can be updated as being utilized for 0.30 hours from the total of three years of operation time since the operating temperature of 110° C. is equivalent to less operating time according to the statistical model.

In a different example, the CPU 255 can convert an operating temperature of 135° C. for 1 hour to an operating temperature of 125° for 1.30 hours to calculate the time-to-failure for the SoC 251. In this example, the time-to-failure for the SoC 251 can be updated as being utilized for 1.30 hours from the total of three years of operation time since the operating temperature of 135° C. is equivalent to more operating time according to the statistical model. In this way, the CPU 255 is able to convert or normalize the plurality of different temperatures to the designated operating temperature and determine a time-to-failure or aging rate of an aging mechanism (e.g., electromigration aging mechanism, bias temperature instability (BTI) aging mechanism, hot carrier injection (HCl) aging mechanism, etc.) for the SoC 251. The detected clocking signals, voltage, current, and/or other real world measurements can be normalized in a similar way to determine the time-to-failure for the SoC 251, determine an aging profile for the SoC 251, and/or generate fault analysis data for the SoC 251 as described herein.

The CPU 255 can be configured to calculate an aging profile for the SoC 251 based on the normalized temperature data and voltage data. In these embodiments, the aging profile for the SoC 251 is calculated based on a comparison of the normalized temperature data and voltage data to an aging mechanism response per temperature data for the SoC 251. As described herein, the time-to-failure for the aging mechanism can be calculated utilizing a designated operating temperature.

However, as described herein, the real world operating temperature of the SoC 251 can be greater than the designated operating temperature or less than the designated operating temperature during normal operation of the SoC 251. In these embodiments, the real world temperature data and real world voltage data of the SoC 251 collected during operation of the SoC 251 can be utilized to update or generate the aging profile that is specific for the SoC 251. The specific aging profile for the SoC 251 can be utilized for altering settings associated with the SoC 251, utilized for generating designated aging profiles for future SoC devices, and/or utilized for analyzing aging profiles of other types of SoCs based on real world operation data.

In other embodiments, the CPU 255 can be executed to calculate an aging profile for the SoC 251 based on the normalized temperature data and voltage data for a period of time. As described herein, the aging profile for the SoC 251 can include a calculated time-to-failure based on the statistical model for the SoC 251 and the normalized real world data for the SoC 251. In some embodiments, the aging profile can be the limiting factor or the major factor in the time-to-failure for the SoC 251. In this way, the aging profile can be utilized to determine the time-to-failure compared to utilizing other aging profiles for other aging mechanisms.

The CPU 255 can be configured to update a designated time-to-failure for the SoC 251 based on the calculated aging profile. As described herein, the aging profile for the SoC 251 can be a rate limiting factor for the time-to-failure for the SoC 251. In this way, the calculated aging profile, utilizing operational data associated with the SoC 251, can be utilized to determine or update a time-to-failure for the SoC 251. The designated time-to-failure can be a manufacturer's time-to-failure based on the designated operating temperature for the entire time period of operation. As described herein, the designated time-to-failure can be changed based on the normalized real-time operational temperature of the SoC 251 during real world conditions.

The CPU 255 can be configured to update SoC settings based on the updated time-to-failure. In these embodiments, the SoC settings include voltage settings associated with the voltage regulator 256. As described herein, the SoC 251 settings can be altered based on the updated time-to-failure for the SoC 251. In some embodiments, the updated or altered SoC settings can be executed to extend the updated time-to-failure of the SoC 251. For example, the SoC settings can be altered to facilitate lowering an operating temperature of the SoC 251 such that the updated time-to-failure is increased. In some embodiments, the CPU 255 can determine that the time-to-failure of the aging profile for the SoC 251 has decreased at a particular rate over a period of time that exceeds a threshold. In these embodiments, the SoC settings can be altered to facilitate altering the decrease of the time-to-failure of the aging profile for future operations.

The CPU 255 can be configured to generate fault analysis data for the SoC 251 based on the updated time-to-failure. As used herein, fault analysis data includes a description of a reason or a plurality of reasons for the SoC 251 failure. In some embodiments, the fault analysis data can include an analysis of the collected data of the SoC 251 during operation that were potential reasons for a failure of the SoC 251. In this way, the operation of the SoC 251 can be analyzed over time to determine a root cause or a plurality of causes that resulted in a failure of the SoC 251. In some embodiments, the fault analysis data can be utilized for generating future SoC devices to increase performance without decreasing a time-to-failure for the SoC 251.

The CPU 255 can be configured to determine when a defect associated with the SoC 251 is associated with the temperature data or voltage data based on the updated time-to-failure. As described herein, fault analysis data can be determined for the SoC 251. In some embodiments, a defect associated with the SoC 251 can be identified based on the collected data. For example, the updated time-to-failure data based on the real world temperature data and/or voltage data can be utilized to determine if the SoC 251 failure was due to normal aging under real world conditions, abnormal aging (e.g., abusive conditions, etc.) under real world conditions, or if there was a defect of the SoC 251. For example, if a failure occurs relatively sooner than an expected failure based on the updated time-to-failure of the aging profile, it can be determined that there is a potential defect that caused the failure. In other embodiments, a normal failure without a defect can be identified for the SoC 251 when a failure of the SoC 251 is relatively close to the updated time-to-failure of the aging profile.

The CPU 255 can be configured to generate lifetime durability data from the SoC 251 based on the aging profile (e.g., electromigration aging profile, bias temperature instability (BTI), hot carrier injection (HCl), etc.) for the SoC 251 over a lifetime of the SoC 251. In some embodiments, the lifetime durability data can include data collected over a lifetime of the SoC 251. For example, the fault analysis data can be an analysis of the temperature data, voltage data, clock data, and/or other data over the lifetime of the SoC 251. The performance data of the SoC along with the collected data can be utilized to analyze how the aging profile of the SoC 251 was affected by the collected temperature data, voltage data, clock data and/or other data of the SoC 251.

In other embodiments, the CPU 255 can be executed to determine lifetime durability data for the SoC 251 based on a plurality of aging profiles for the SoC 251 over a lifetime of the SoC 251. In some embodiments, the lifetime durability data for the SoC 251 can be based on the data collected over a lifetime of operation of the SoC 251. In some embodiments, the functionality or performance of the SoC 251 can be compared to the aging profile data to determine how the operation of the SoC 251 affects the functionality or performance of the SoC 251 over time. In this way, real world data can be utilized to determine performance degradation of the SoC 251 over a lifetime of the device.

The CPU 255 can be configured to store the aging profile for the SoC 251 in response to a signal to turn off a system associated with the SoC 251. As described herein, the aging profile for the SoC 251 can be stored at the NVM 253 during a system activation and/or a system deactivation. In this way, the collected data utilized to update the aging profile and/or time-to-failure for the SoC 251 can be stored or saved in non-volatile memory at activation and deactivation. In some embodiments, the stored aging profile can be stored such that the data can be analyzed after a failure of the SoC 251.

In other embodiments, the CPU 255 can be executed to store the aging data in response to receiving a startup signal or a shutdown signal. As described herein, the data related to the aging mechanism can be stored periodically by the SoC 251. In these embodiments, the SoC 251 can store the data in a non-volatile memory (e.g., NVM 253, etc.) such that the data can be extracted even if the SoC 251 experiences a failure. In some embodiments, the system 250 can include a cell aging monitor to collect aging data for a plurality of circuit types associated with the SoC. In some embodiments, the cell aging monitor can include a circuit that includes different types of electrical components (e.g., MOSFET, etc.) that can be monitored over the lifetime of the SoC 251 to determine if there is more or less degradation of a particular type of electrical components.

In a specific example, a first circuit can be provided with electrical current during normal operation and a second circuit that includes the same types of electrical component can be provided with electrical current only during a testing operation. In this way, the output of the testing operation of the second circuit can be compared to the output of the first circuit to determine degradation of the components of the first circuit. Although this specific example can be utilized to monitor degradation of the components, other types of monitors can be utilized with the current disclosure. In some embodiments, the CPU 255 can be executed to correlate the aging data with the temperature data and the voltage data with the time data received by the timer 252. By utilizing the aging data for the electrical components with the aging profile data for the SoC 251, the CPU 255 can determine how the performance is affected by the aging mechanism and how the performance may be affected by other types of degradation.

In some embodiments, the system 250 can include a domain sensor to determine voltage domains during operation of the SoC 251 and during shut down of the SoC 251. In some examples, the domain sensor can monitor the voltage domains of the SoC 251 to determine when that portions of the SoC 251 are operating within specific limits or thresholds. For example, the SoC 251 can utilize different power profiles that can utilize different voltage domains. In these embodiments, the determined voltages provided to the SoC 251 can be stored with the corresponding power profiles.

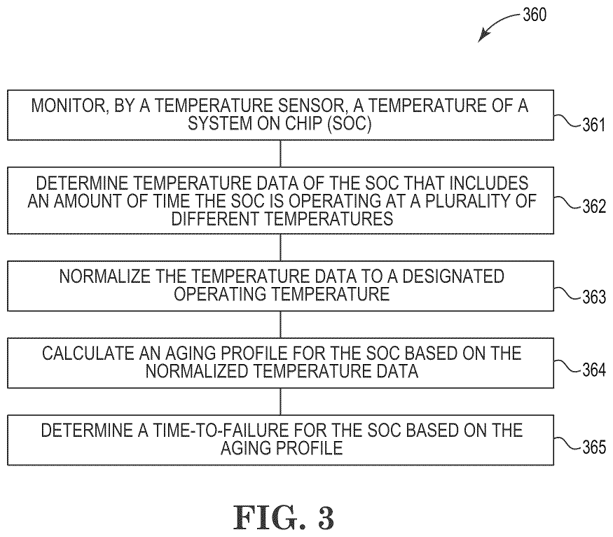

FIG. 3 illustrates a method 360 for determining an aging profile in accordance with some embodiments of the disclosure. The method 360 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 360 is performed by the aging profile component 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 361, the method 360 can be executed to monitor, by a temperature sensor, a temperature of a system on chip (SoC). In some embodiments, the method 360 can include a voltage sensor to determine a voltage provided to the SoC. In addition, the method 360 can be executed by a frequency sensor to determine a frequency of clocking signals of the SoC. In this way, a temperature, a voltage and/or an operating frequency of the SoC can be monitored. Although specific embodiments are discussed utilizing a temperature sensor, the data collected by the voltage sensor and frequency sensor can be normalized in a similar way to update an aging profile of the SoC based on real world usage.

As described herein, monitoring the temperature of the SoC can include utilizing a temperature sensor device associated with the SoC to determine a temperature of the SoC over a period of time. In some examples, the temperature sensor can detect a temperature of the SoC during operation of the SoC and store the detected temperature data with corresponding time data.

At operation 362, the method 360 can be executed to determine temperature data and/or voltage of the SoC that includes an amount of time the SoC is operating at a plurality of different temperatures and/or voltages. As described herein, the processor (e.g., CPU 255 as referenced in FIG. 2, etc.) can extract the stored temperature data from a memory resource (e.g., NVM 253 as referenced in FIG. 2, etc.) and corresponding time data to determine an amount of time that the SoC is operating at different temperatures.

In some embodiments, the method 360 can be executed to correlate the temperature data with voltage data of the SoC that includes an operating voltage of the SoC at the plurality of different temperatures. As described herein, the voltage data can be stored at a memory resource with the corresponding time data in a similar way as the temperature data. In this way, the method 360 can extract the voltage data and temperature data at the corresponding time to correlate the voltage data to the temperature data.

In these embodiments, the method 360 can be executed to correlate the temperature data with voltage data of the SoC that includes an operating voltage of the SoC at the plurality of different temperatures. In these embodiments, the method 360 can be executed to update the aging profile (e.g., electromigration aging profile, bias temperature instability (BTI), hot carrier injection (HCl), etc.) based on the operating voltage of the SoC at the plurality of different temperatures. As described herein, the temperature of the SoC can affect the aging mechanism of components associated with the SoC. For example, the aging mechanism can occur at a first rate while operating at a first temperature and can occur at a second rate while operating at a second temperature.

In some embodiments, a statistical representation of the aging mechanism for a SoC can be for a particular operation temperature. In these embodiments, the detected temperature from the SoC can be normalized to the particular operation temperature such the time spent at the particular operation temperature is adjusted to reflect the statistical representation.

In some embodiments, the method 360 can be executed to correlate the temperature data with clocking data of the SoC that includes an operating clock frequency of the SoC at the plurality of different temperatures. In a similar way to how the temperature can affect the aging mechanism, the operating clock frequency and/or voltage can also affect the aging mechanism. In this way, the time spent at different operating clock frequencies can be normalized to a designated clock frequency utilized in a statistical model for aging mechanisms of an SoC.

At operation 363, the method 360 can be executed to normalize the temperature data to a designated operating temperature. In these embodiments, the designated operating temperature is a temperature range utilized to calculate the designated time-to-failure for the SoC. For example, the particular operation temperature can be a normalized aging factor per temperature value. In this example, the temperature value can be 125 degrees Celsius (° C.) and a time to failure can be approximately three years. That is, the time-to-failure for a particular SoC would be three years if it were operating at 125° C. In this example, the detected temperature data can be normalized to 125° C. and the time-to-failure can be normalized for the time period of operation at 125° C. For example, one hour at a detected temperature of 110° C. can be normalized to 0.31 hours at 125° C. In addition, the method 360 can normalize the 0.31 hours at 125° C. for a particular detected voltage, a particular detected current, and/or at a particular detected frequency. In some embodiments, the 0.31 hours at 125° C. can be increased or decreased based on a normalization of the time-to-failure for the particular detected voltage, the particular detected current, and/or the particular detected frequency (e.g., clocking frequency, etc.). In this way, the time-to-failure of the aging profile for the SoC can be updated based on real-time temperature operation, real time voltage operation, real time current operation, and/or real time frequency operation of the SoC.

At operation 364, the method 360 can be executed to calculate an aging profile for the SoC based on the normalized temperature data. As described herein, the calculated aging profile for the SoC can be based on the normalized temperature data, normalized voltage data, and/or normalized clock data. In some embodiments, the calculated aging profile can be based on an updated statistical model for the SoC.

At operation 365, the method 360 can be executed to determine a time-to-failure for the SoC based on the aging profile. As described herein, the time-to-failure for the SoC can be updated to determine a current time to failure based on the amount of time the SoC has operated at particular temperatures, particular voltages, and/or particular clocking frequencies. In some embodiments, the method 360 can be executed to update a designated time-to-failure for the SoC based on the determined time-to-failure. As described herein, the designated time-to-failure can be a time-to-failure for the SoC designated by a manufacturer and the designated time-to-failure can be updated based on the real world conditions of operation. In some embodiments, the method 360 can be executed to update the aging profile based on the operating clock frequency of the SoC at the plurality of different temperatures.

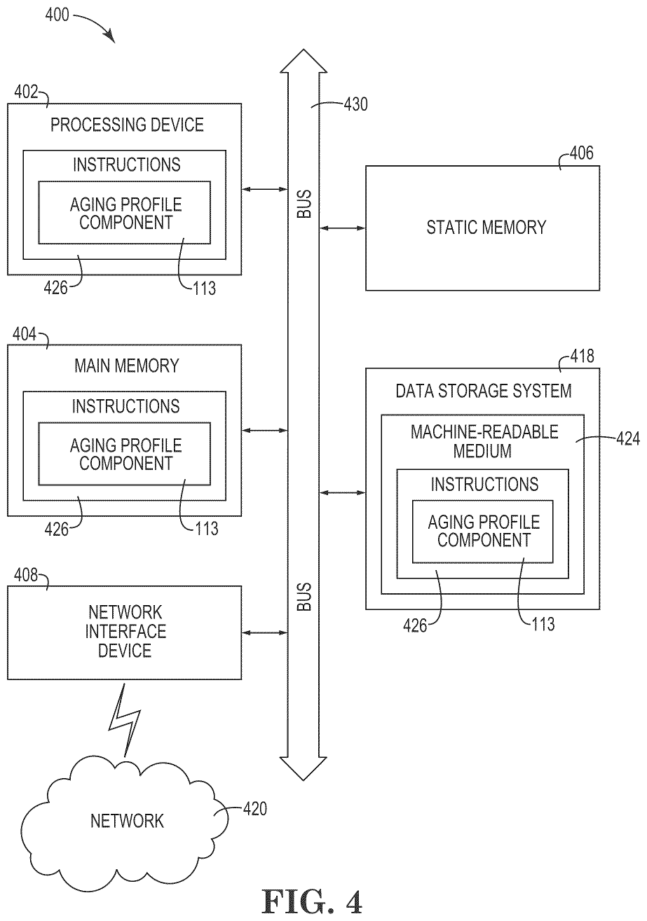

FIG. 4 is a block diagram of an example computer system 400 in which embodiments of the disclosure may operate. For example, FIG. 4 illustrates an example machine of a computer system 400 within which a set of instructions, for causing the machine to perform any one or more of the methodologies discussed herein, can be executed. In some embodiments, the computer system 400 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the aging profile component 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 400 includes a processing device 402, a main memory 404 (e.g., read-only memory (ROM), flash memory, dynamic random access memory (DRAM) such as synchronous DRAM (SDRAM) or Rambus DRAM (RDRAM), etc.), a static memory 406 (e.g., flash memory, static random access memory (SRAM), etc.), and a data storage system 418, which communicate with each other via a bus 430.

In one embodiment, the instructions 426 include instructions to implement functionality corresponding to an aging profile component (e.g., the aging profile component 113 of FIG. 1). While the machine-readable storage medium 424 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer).

In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc. In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A method, comprising:
monitoring, by a temperature sensor, a temperature of a system on chip (SoC);
determining temperature data of the SoC that includes an amount of time the SoC is operating at a plurality of different temperatures;
normalizing the temperature data to a designated operating temperature;
calculating an aging profile for the SoC based on the normalized temperature data; and
determining a time-to-failure for the SoC based on the aging profile.

2. The method of claim 1, further comprising normalizing voltage data of the SoC that includes an amount of time the SoC is operating at an operating voltage.

3. The method of claim 2, further comprising updating the aging profile based on the normalized voltage data.

4. The method of claim 1, further comprising updating a designated time-to-failure for the SoC based on the determined time-to-failure.

5. The method of claim 4, wherein the designated operating temperature is a temperature range utilized to calculate the designated time-to-failure for the SoC.

6. The method of claim 1, further comprising normalizing clocking data of the SoC that includes an amount of time the SoC is operating at a particular clock frequency.

7. The method of claim 1, further comprising updating the aging profile based on the normalized clocking data.

8. An apparatus, comprising:
a system on chip (SoC);
a voltage regulator associated with the SoC;
a temperature sensor associated with the SoC; and
a controller coupled to the SoC, the voltage regulator, and the temperature sensor, wherein the controller is configured to:
monitor temperature data of the SoC received by the temperature sensor;
monitor voltage data provided to the SoC by the voltage regulator;
correlate the temperature data and the voltage data with time data;
normalize the temperature data to a designated operating temperature of the SoC;
calculate an electromigration aging profile for the SoC based on the normalized temperature data and voltage data; and
update a designated time-to-failure for the SoC based on the calculated electromigration aging profile.

9. The apparatus of claim 8, wherein the controller is configured to update SoC settings based on the updated time-to-failure.

10. The apparatus of claim 9, wherein the SoC settings include voltage settings associated with the voltage regulator.

11. The apparatus of claim 8, wherein the electromigration aging profile for the SoC is calculated based on a comparison of the normalized temperature data and voltage data to electromigration response per temperature data for the SoC.

12. The apparatus of claim 8, wherein the controller is configured to generate fault analysis data for the SoC based on the updated time-to-failure.

13. The apparatus of claim 8, wherein the controller is configured to generate lifetime durability data from the SoC based on the electromigration aging profile for the SoC over a lifetime of the SoC.

14. The apparatus of claim 8, wherein the controller is further configured to determine when a defect associated with the SoC is associated with the temperature data, current data, frequency data, or voltage data based on the updated time-to-failure.

15. The apparatus of claim 8, wherein the controller is further configured to store the electromigration aging profile for the SoC in response to a signal to: turn off a system associated with the SoC, enter a low power mode, enter a hibernation mode, or store periodically.

16. A system comprising:
a system on chip (SoC);
a timer associated with the SoC;
a voltage regulator associated with the SoC;
a temperature sensor associated with the SoC; and
a processing device coupled to the SoC, wherein the processing device is configured to:
monitor temperature data of the SoC received by the temperature sensor with corresponding time data received by the timer;
monitor voltage data and current data provided to the SoC by the voltage regulator with corresponding time data received by the timer;
correlate the temperature data and the voltage data with corresponding time data received by the timer;
normalize the temperature data to a designated operating temperature of the SoC;
calculate an electromigration aging profile for the SoC based on the normalized temperature data and voltage data for a period of time; and
determine lifetime durability data for the SoC based on a plurality of electromigration aging profiles for the SoC over a lifetime of the SoC.

17. The system of claim 16, wherein the processing device is configured to store the electromigration aging data in response to receiving a startup signal or a shutdown signal.

18. The system of claim 16, comprising a cell aging monitor to collect aging data for a plurality of circuit types associated with the SoC.

19. The system of claim 18, wherein the processing device is configured to correlate the aging data with the temperature data and the voltage data with the time data received by the timer.

20. The system of claim 16, comprising a domain sensor to determine voltage domains during operation of the SoC and during shut down of the SoC.
